(19) United States
(12) Patent Application Publication
(10) Pub. No.: US 2026/0005512 A1
(43) Pub. Date: Jan. 1, 2026

(54) AC VOLTAGE AND DC VOLTAGE MIXING PROTECTION

(71) Applicant: VISTEON GLOBAL TECHNOLOGIES, INC., Van Buren Township, MI (US)

(72) Inventors: Iegor S. Sheremetiev, Sofia (BG); Mathew Breton, Westland, MI (US); Michael C. Lees, Chelmsford (GB); Ivan S. Hristov, Sofia (BG); Laurent Ribes, Livilliers (FR)

(73) Assignee: VISTEON GLOBAL TECHNOLOGIES, INC., Van Buren Township, MI (US)

(21) Appl. No.: 19/252,928

(22) Filed: Jun. 27, 2025

Related U.S. Application Data
(60) Provisional application No. 63/665,768, filed on Jun. 28, 2024.

(51) Int. Cl. H02H 3/50; B60L 53/16; B60L 53/22; H03M 1/12

(52) U.S. Cl. CPC H02H 3/50; B60L 53/16; B60L 53/22; B60L 2210/30; H03M 1/12

(57) ABSTRACT

A protection circuit includes an analog-to-digital converter, a processor, and a control circuit. The analog-to-digital converter generates a sequence of digital values by digitizing a high-voltage signal within a high-voltage area of a vehicle. The control circuit controls multiple contactors coupled to the charging socket in response to a configuration signal. The processor determines if the sequence of digital values represents one of an alternating voltage and a steady-state voltage, asserts the configuration signal to command the control circuit to close a pair of DC contactors in response to the sequence of digital values representing the steady-state voltage, and negates the configuration signal to command the control circuit to open the pair of DC contactors in response to the sequence of digital values representing the alternating voltage to prevent a mixture of the alternating voltage and the steady-state voltage in the high-voltage area.

### CROSS-REFERENCE TO RELATED APPLICATIONS

This application claims the benefit of U.S. Provisional Application No. 63/665,768, filed Jun. 28, 2024, which is hereby incorporated by reference in its entirety.

### TECHNICAL FIELD

The present disclosure generally relates to circuits and methods for protecting against mixing of an AC voltage and a DC voltage.

### BACKGROUND

Current state-of-art battery junction boxes in electric vehicles could potentially allow an inadvertent mixing of AC electrical power from a charging station and DC electrical power from a high-voltage DC battery in the vehicle. For example, the North American Charging System (NACS)-type charging systems combines an AC charging path and a DC charging path prior to entering the vehicle. A failure or a component that does not perform as specified could result in the high-voltage DC battery being exposed to the external AC charging station and vice versa.

Accordingly, those skilled in the art continue with research and development efforts in the field of protecting against mixing of AC voltages and DC voltages.

### SUMMARY

A protection circuit is provided herein. The system includes an analog-to-digital converter, a control circuit, and a processor. The analog-to-digital converter is operational to generate a sequence of digital values by digitizing a high-voltage signal within a high-voltage area of a vehicle. The vehicle includes a high-voltage battery and a charging socket. The control circuit is operational to control a plurality of contactors coupled to the charging socket in response to a configuration signal. The processor operational to determine if the sequence of digital values represents one of an alternating voltage and a steady-state voltage, assert the configuration signal to command the control circuit to close a pair of DC contactors among the plurality of contactors in response to the sequence of digital values representing the steady-state voltage, and negate the configuration signal to command the control circuit to open the pair of DC contactors in response to the sequence of digital values representing the alternating voltage to prevent a mixture of the alternating voltage and the steady-state voltage in the high-voltage area.

In one or more embodiments, the protection circuit includes a detector circuit operational to monitor the high-voltage signal, assert an enable signal while the high-voltage signal is detected as the steady-state voltage, and negate the enable signal while the high-voltage is detected as the alternating voltage.

In one or more embodiments of the protection circuit, the control circuit is further operational to close the pair of DC contactors in response to the enable signal being asserted and the configuration signal being asserted, and open the pair of DC contactors in response to at least one of the enable signal being negated and the configuration signal being negated.

In one or more embodiments, the protection circuit includes a digital isolator circuit operational to transfer the enable signal from the high-voltage area to the control circuit in a low-voltage area of the vehicle.

In one or more embodiments of the protection circuit, the detector is implemented solely in hardware.

In one or more embodiments, the protection circuit includes a bandpass filter circuit connected between the charging socket and the analog-to-digital converter.

In one or more embodiments, the protection circuit includes a capacitive coupler circuit between the charging socket and the bandpass filter circuit.

In one or more embodiments, the protection circuit includes an isolation circuit operational to transfer the sequence of digital values from the high-voltage area to the processor in a low-voltage area of the vehicle.

In one or more embodiments of the protection circuit, the high-voltage signal is approximately 200 to 1000 volts DC.

In one or more embodiments of the protection circuit, the high-voltage signal is approximately 100 to 260 volts AC.

A method for preventing a mixture of an alternating voltage and a steady-state voltage is provided herein. The method includes generating with an analog-to-digital converter a sequence of digital values by digitizing a high-voltage signal within a high-voltage area of a vehicle. The vehicle includes a high-voltage battery and a charging socket. The method includes controlling with a control circuit a plurality of contactors coupled to the charging socket in response to a configuration signal. Determining with a processor if the sequence of digital values represents one of an alternating voltage and a steady-state voltage, asserting with the processor the configuration signal to command the control circuit to close a pair of DC contactors among the plurality of contactors in response to the sequence of digital values representing the steady-state voltage, and negating with the processor the configuration signal to command the control circuit to open the pair of DC contactors in response to the sequence of digital values representing the alternating voltage to prevent the mixture of the alternating voltage and the steady-state voltage in the high-voltage area.

In one or more embodiments, the method includes monitoring with a detector the high-voltage signal with a detector circuit, asserting an enable signal while the high-voltage signal is detected as the steady-state voltage, and negating the enable signal while the high-voltage is detected as the alternating voltage.

In one or more embodiments, the method includes closing the pair of DC contactors in response to the enable signal being asserted and the configuration signal being asserted, and opening the pair of DC contactors in response to at least one of the enable signal being negated and the configuration signal being negated.

In one or more embodiments, the method includes transferring with a digital isolator the enable signal from the high-voltage area to the control circuit in a low-voltage area of the vehicle.

In one or more embodiments of the method, the monitoring is performed solely in hardware.

In one or more embodiments, the method includes bandpass filtering a signal between the charging socket and the analog-to-digital converter.

In one or more embodiments, the method includes capacitively coupling the charging socket to the bandpass filtering.

In one or more embodiments, the method includes transferring with an isolation circuit the sequence of digital values from the high-voltage area to the processor in a low-voltage area of the vehicle.

In one or more embodiments of the method, the high-voltage signal is approximately 200 to 1000 volts DC, and the high-voltage signal is approximately 100 to 260 volts AC.

A vehicle is provided herein. The vehicle includes a high-voltage area that houses a high-voltage battery, a charging socket accessible from external to the vehicle, an analog-to-digital converter operational to generate a sequence of digital values by digitizing a high-voltage signal within the high-voltage area, a control circuit operational to control a plurality of contactors coupled to the charging socket in response to a configuration signal, and a processor. The processor is operational to determine if the sequence of digital values represents one of an alternating voltage and a steady-state voltage, assert the configuration signal to command the control circuit to close a pair of DC contactors among the plurality of contactors in response to the sequence of digital values representing the steady-state voltage, and negate the configuration signal to command the control circuit to open the pair of DC contactors in response to the sequence of digital values representing the alternating voltage to prevent a mixture of the alternating voltage and the steady-state voltage in the high-voltage area.

The above features and advantages and other features and advantages of the present teachings are readily apparent from the following detailed description of the best modes for carrying out the teachings when taken in connection with the accompanying drawings.

### BRIEF DESCRIPTION OF THE DRAWINGS

FIG. 1 illustrates a context of a system in accordance with one or more exemplary embodiments.

FIG. 2 illustrates a functional block diagram of the system in accordance with one or more exemplary embodiments.

FIG. 3 illustrates a schematic block diagram of a protection circuit in accordance with one or more exemplary embodiments.

FIG. 4 illustrates a schematic block diagram of another protection circuit in accordance with one or more exemplary embodiments.

FIG. 5 illustrates a schematic diagram of a detector circuit in accordance with one or more exemplary embodiments.

FIG. 6 illustrates a schematic diagram of a contactor driver disable circuit in accordance with one or more exemplary embodiments.

FIG. 7 illustrates a schematic diagram of another contactor driver disable circuit in accordance with one or more exemplary embodiments.

### DETAILED DESCRIPTION

Various embodiments of a protection circuit and/or a method generally prevent a mixing of direct-current (DC) voltage from mixing with an alternating-current (AC) voltage. The DC voltage may be a steady-state voltage within a high-voltage area of an electric vehicle. The DC voltage may be created by an external charging station and/or an internal DC battery pack. The AC voltage may be an alternating voltage generated by a charging station external to the electric vehicle. In various embodiments, the charging station may present the alternating voltage or the steady-state voltage to a charging socket of the electric vehicle, depending on a handshaking protocol exchanged between the charging station and the vehicle at the start of a charging session. The charging socket may be compliant with a North American Charging System (NACS) standard, or similar standards. In the NACS standard, two conductors are used to convey the steady-state voltage, a single-phase alternating voltage, and two lines of a split-phase (2-phase) alternating voltage in different configurations. A protection circuit/method implemented in the vehicle generally detects if the alternating voltage or the steady-state voltage is present in a high-voltage area of the vehicle. If the alternating voltage is detected, DC contactors (e.g., DC Fast Charge contactors) are prevented from closing, or are commanded to open if already closed, thereby avoiding potential damage to the vehicle, the charging station and/or connections in-between. If the steady-state voltage is detected, the DC contactors are closed and, where implemented, link contactors are opened.

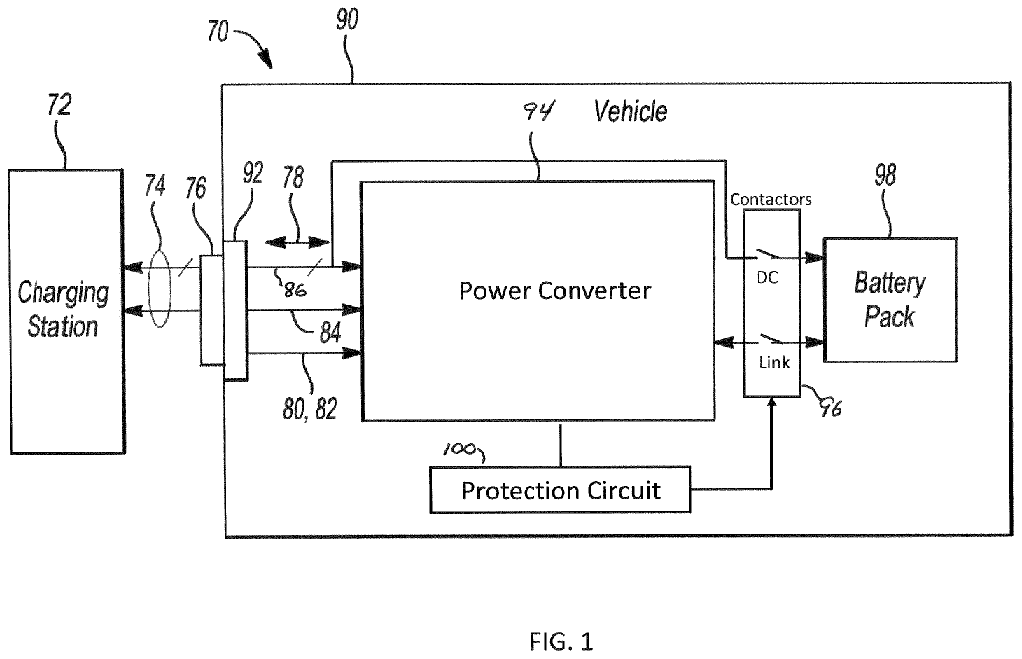

Referring to FIG. 1, a schematic diagram illustrating a context of a system 70 is shown in accordance with one or more exemplary embodiments. The system 70 generally includes a charging station 72 and a vehicle 90. The charging station 72 includes a charging cable 74 and a charging plug 76. The vehicle 90 includes a charging socket 92, a power converter 94, a contactor circuit 96, a battery pack 98 and a protection circuit 100.

Electrical power 78 may flow between the charging station 72 and the protection circuit 100 in either direction via the charging cable 74, the charging plug 76, charging wires 86, and the charging socket 92. In some situations, the electrical power 78 may be single-phase alternating-current (AC) electrical power. In other situations, the electrical power 78 may be direct-current (DC) electrical power.

A control signal 80 may be presented from the charging plug 76, through the charging socket 92 to the protection circuit 100. The control signal 80 may convey one of multiple commands 82 to protection circuit 100. The commands 82 instruct the protection circuit 100 about the type of electrical power 78 (e.g., AC or DC) and a direction that the electrical power 78 is flowing (e.g., into the protection circuit 100 via the charging socket 92 or out of the charging socket 92 from the protection circuit 100.

A communication signal 84 may be exchanged between the charging station 72 and the protection circuit 100 via the charging cable 74, the charging plug 76, and the charging socket 92. The communication signal 84 may provide standard signaling information between the charging station 72 and the protection circuit 100 to start, control, and stop the flow of the electrical power 78.

The charging station 72 is operational to provide the electrical power 78 (e.g., electrical current at a voltage) to the vehicle 90 to recharge onboard batteries of the vehicle 90. In various embodiments, the charging stations 72 may be compliant with the North American Charging System (NACS), being standardized as SAE J3400, the SAE International J1772 standard and/or the International Electrotechnical Commission (IEC) 61851-1 standard. The charging stations 72 may be a Level 1 AC, a Level 2 AC, a Level 1 DC, a Level 2 DC or an NACS (DC, AC single phase and/or AC split phase) charger. Other charging standards may be implemented to meet the design criteria of a particular application. Some charging stations 72 may be placed at fixed locations. Other charging stations 72 may be mobile.

The charging plug 76 implements an electric charging handle. The charging socket 92 implements a vehicle charging receptacle. The charging plug 76 is connectable and disconnectable from the charging socket 92. The charging plug 76 and the charging socket 92 are operational to transfer the electrical power 78, control signal 80, and the communication signal 84 between the charging station 72 and the vehicle 90.

The vehicle 90 implements an electric-powered vehicle, a hybrid vehicle, or a plug-in hybrid vehicle. The vehicles 90 may implement Level 1 AC, Level 2 AC, Level 1 DC, Level 2 DC or NACS (DC, AC single phase and/or AC split phase) charging capabilities. Other standards may be implemented to meet the design criteria of a particular application. In various embodiments, the vehicle 90 may include, but is not limited to, a passenger vehicle, a truck, an autonomous vehicle, a motorcycle, a boat, and/or an aircraft. In some embodiments, the vehicles 90 may be a stationary object such as a room, a booth and/or a structure. Other types of vehicles 90 may be implemented to meet the design criteria of a particular application.

The charging socket 92 implements a high-voltage socket through which the battery pack 98 is recharged. The charging socket 92 is accessible from external to the vehicle 90. In various embodiments, the charging socket 92 may be operational to provide the electrical power 78 out from the vehicle 90 to external loads. In various embodiments, the charging socket 92 may be compliant with the North American Charging System, the SAE International J1772 standard and/or the International Electrotechnical Commission (IEC) 61851-1 standard.

The power converter 94 is operational to accept the single-phase AC electrical power (e.g., electrical power 78) from the charging station 72 and present the DC electrical power to the contactor circuit 96. While operating in a single-phase input mode, the power converter 94 is operational to convert an input single-phase AC electrical power to a first direct-current (DC) electrical power. In various embodiments, the first DC electrical power may be suitable to charge the battery pack 98. In other embodiments, the first DC electrical power may be converted to a second DC electrical power suitable for charging the battery pack 98. While operating in a single-phase output mode, the power converter 94 may receive the second DC electrical power from the battery pack 98, convert the second DC electrical power to the first DC electrical power, and subsequently convert the first DC electrical power to an output single-phase AC electrical power. In some configurations, the power converter 94 may receive the first DC electrical power directly from the battery pack 98, and convert the first DC electrical power to the output single-phase AC electrical power. In various embodiments, the power converter 94 may be located in the vehicle 90. In other embodiments, the power converter 94 may reside at a location independent of the vehicle 90 (e.g., a portable power converter 94 or part of the charging station 72)

The contactor circuit 96 implements one or more high-voltage contactors. The contactor circuit 96 is operational to transfer steady-state voltages (e.g., DC power) between the battery pack 98 and the charging stations 72. In various embodiments, the contactor circuit 96 is operational to transfer steady-state voltages between the battery pack 98 and the power converter 94. Control of the contactor circuit 96 is provided by the protection circuit 100.

The battery pack 98 implements as a high-voltage battery or rechargeable energy storage system. The battery pack 98 is configured to store electrical energy. The battery pack 98 is generally operational to receive electrical power from the charging station 72 and provide electrical power to other components of the vehicle 90. The battery pack 98 may include multiple battery modules electrically connected in series and/or in parallel. In various embodiments, the battery pack 98 may provide approximately 200 to 1000 volts DC (direct current) electrical potential. Other battery voltages may be implemented to meet the design criteria of a particular application.

The protection circuit 100 implements a monitoring technique that prevents the mixing of the AC electrical power and the DC electrical power inside the vehicle 90. The protection circuit 100 may monitor a charging voltage of the electrical power 78 received from the charging station 72 in a high voltage area of the vehicle 90. The monitoring may be accomplished by filtering and digitizing the charging voltage to generate a sequence of digital values. The digital values are presented to a processor in a low-voltage area of the vehicle 90. The processor determines if the charging voltage is alternating (e.g., an AC charging) or steady-state (e.g., a DC charging).

If the AC charging is determined, the processor sends one or more commands to a control circuit to (i) open the DC contactors between the charging socket 92 and the battery pack 98 and (ii) close link connectors on the output nodes of an AC-to-DC power converter to present DC electrical power to the battery pack 98. Where implemented, the processor may also send one or more commands to the control circuit to close additional main contactors (not shown) between the charging socket 92 and input nodes of the AC-to-DC power converter to facilitate the conversion of the electrical power 78 into a DC voltage.

If the DC charging is determined, the processor sends one or more command to the control circuit to (i) open the link contactors between the output nodes of AC-to-DC power converter and the battery pack 98 and (ii) close the DC contactors between the charging socket 92 and the battery pack 98. Where implemented, the processor may also command the control circuit to open the additional main contactors between the charging socket 92 and the input nodes of the AC-to-DC power converter.

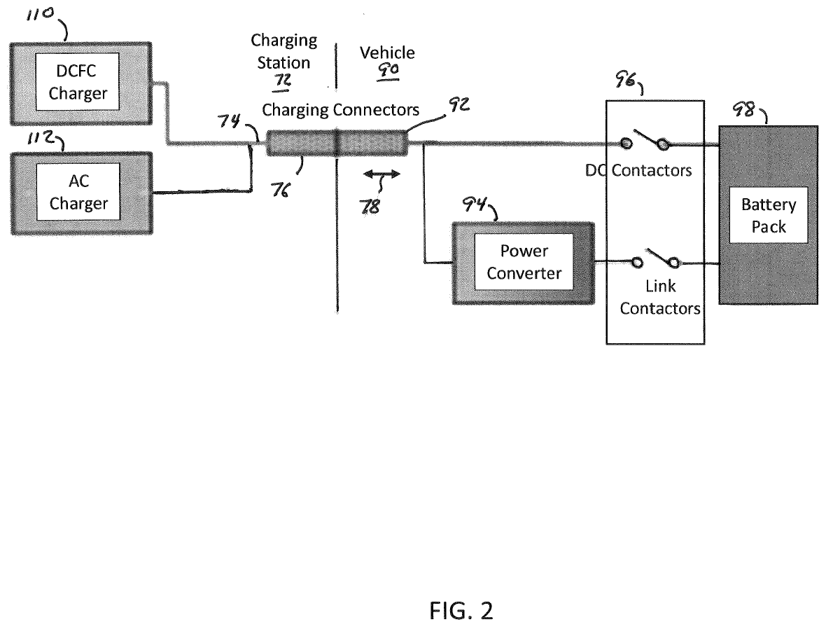

FIG. 2 illustrates a functional block diagram of an example implementation of the system 70 in accordance with one or more exemplary embodiments. The system 70 includes the charging station 72 and the vehicle 90.

The charging station 72 generally includes the charging cable 74, the charging plug 76, and one or more power supplies 110-112. In some embodiments, the charging station 72 may include a DC Fast Charge (DCFC) power supply 110. The DCFC power supply 110 is operational to provide DC electrical power to the vehicle 90 during a recharging session. In other embodiments, the charging station 72 may include an AC power supply 112. The AC power supply 112 is operational to provide AC electrical power to the vehicle 90 during a recharging session. In some embodiments, the charging station 72 may include both the DCFC power supply and the AC power supply 112.

The vehicle 90 generally includes the charging socket 92, the power converter 94, the contactor circuit 96, and the battery pack 98.

During a DC charging session, the charging station 72 provides steady-state high-voltage electrical power 78 through a pair of wires in the charging plug 76 and the charging socket 92 to the vehicle 90. The DC electrical power 78 is routed through the contactor circuit 96 (e.g., one or more “DC” contactors) to the battery pack 98. During an AC charging session, the charging station 72 provides alternating high-voltage electrical power 78 through the charging plug 76 and the charging socket 92 to the vehicle 90. The AC electrical power 78 is routed through the power converter 94, converted to DC electrical power, passed through the contactor circuit 96 (e.g., one or more link contactors) and recharges the battery pack 98.

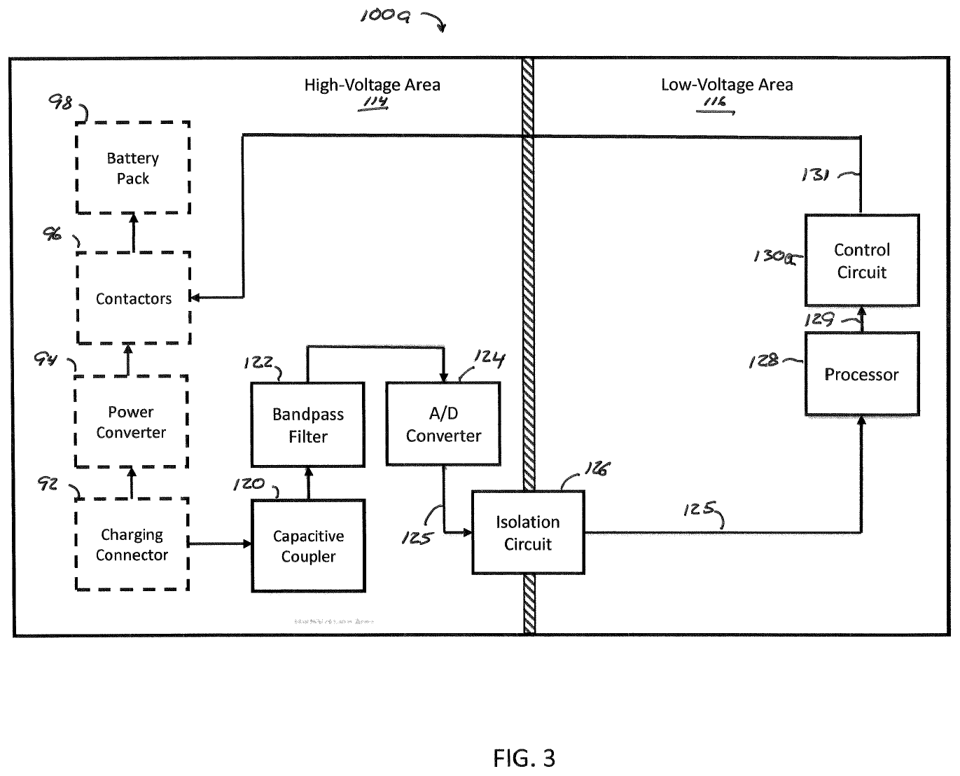

FIG. 3 illustrates a schematic block diagram of an example implementation of a protection circuit 100a in accordance with one or more exemplary embodiments. The protection circuit 100a may be a variation of the protection circuit 100 (FIG. 1). The protection circuit 100a may be spread among a high-voltage area 114 of the vehicle 90 and a low-voltage area 116 of the vehicle. The high-voltage area 114 may include the charging socket 92, the power converter 94, the contactor circuit 96 and the battery pack 98. The protection circuit 100a generally includes a capacitive coupler circuit 120, a bandpass filter circuit 122 an analog-to-digital (A/D) converter circuit 124, and a high-voltage side of an isolation circuit 126 in the high-voltage area 114. The protection circuit 100a also includes a low-voltage side of the isolation circuit 126, a processor 128 and a control circuit 130a in the low-voltage area 116.

The protection circuit 100a implements a combined hardware and software path solution. The hardware portion includes two high-resistive nets with DC-decoupling (capacitive) in the capacitive coupler circuit 120 and the bandpass filter circuit 122. The voltages are read by the A/D converter circuit 124. The results are transferred to the processor 128 via isolation circuit 126 and results may be determined using software prior to closing the contactors. For continuous protection, the A/D converter circuit 124 is continuously queried. Diagnostics may also be performed using software executed by the processor 128.

The capacitive coupler circuit 120 is operational to provide a capacitive path from the charging socket 92 to the bandpass filter circuit 122. The capacitive coupler circuit 120 is operational to block DC voltages and pass AC voltages.

The bandpass filter circuit 122 is operational to pass AC voltages in a designated frequency band. The designated frequency band is generally from approximately 30 hertz (Hz) to approximately 80 H (e.g., 50 Hz to 60 Hz). The bandpass filter circuit 122 allows AC waveforms to be detected, while suppressing noise and unwanted signals outside that range.

The A/D converter circuit 124 is operational to digitize the filtered signal received from the bandpass filter circuit 122 to create a sequence of digital values 125. A frequency of the digitization may be several times higher than a frequency of the AC electrical power. Where the charging station 72 provides DC electrical power 78, the A/D converter circuit 124 may generate a sequence of zero or near-zero digital values 125 as the steady-state voltage received at the charging socket 92 is blocked by a combination of the capacitive coupler circuit 120 and the bandpass filter circuit 122. Where the charging station 72 provides AC electrical power 78, the A/D converter circuit 124 may generate a sequence of non-zero digital values 125 as the alternating voltage received at the charging socket 92 is passed through the capacitive coupler circuit 120 and the bandpass filter circuit 122. In various embodiments, the A/D converter circuit 124 may be implemented with an ADBMS2960 converted, available from Analog Devices. Other types of A/D converters may be implemented to meet the design criteria of a particular application.

The isolation circuit 126 is operational to pass the sequence of digital values 125 from the high-voltage area 114 to the low-voltage area 116. In various embodiments, the isolation circuit 126 may be implemented as an LTC6829 isoSPI transceiver, available from Analog Device. In various embodiments, the isolation circuit 126 may implement opto-coupling, capacitive coupling, and/or inductive coupling. Other isolation circuits may be implemented to meet the design criteria of a particular application.

The processor 128 is operational to sample the digital values 125 presented into the low-voltage area 116 by the isolation circuit 126. The sampling is used to determine if the sequence of digital values 125 represents an alternating voltage or a steady-state voltage in the high-voltage area 114 (e.g., at the charging socket 92 or shortly thereafter). In various embodiments, the processor 128 may be implemented with an Aurix microcontroller unit (MCU), available from Infineon. Other processors may be implemented to meet the design criteria of a particular application.

If a steady-state voltage is detected, the processor 128 asserts a configuration signal 129 to command the control circuit 130a to open one or more link contactors in the contactor circuit 96, if currently closed, to isolate the power converter 94 from the battery pack 98. The control circuit 130a may subsequently close one or more DC contactors in the contactor circuit 96 to route the DC electrical power 78 from the charging socket 92 to the battery pack 98.

If an alternating voltage is detected, the processor 128 negates (e.g., de-asserts) the configuration signal 129 to command the control circuit 130a to the open the one or more DC contactors, if currently closed, to prevent a mixture of the alternating voltage (e.g., at the charging socket 92) and the steady-state voltage in the high-voltage area (e.g., at the battery pack 98). The control circuit 130a may subsequently close one or more link contactors in the contactor circuit 96 to (i) route the AC electrical power from the charging socket 92 to an input of the power converter 94 and (ii) route the DC electrical power from an output of the power converter 94 to the battery pack 98.

The control circuit 130a is operational to control the open/closed condition and open/closed timing sequences of the contactors in the contactor circuit 96 via control signals 131. The control and timing may be based on the configuration signal 129 received from the processor 128.

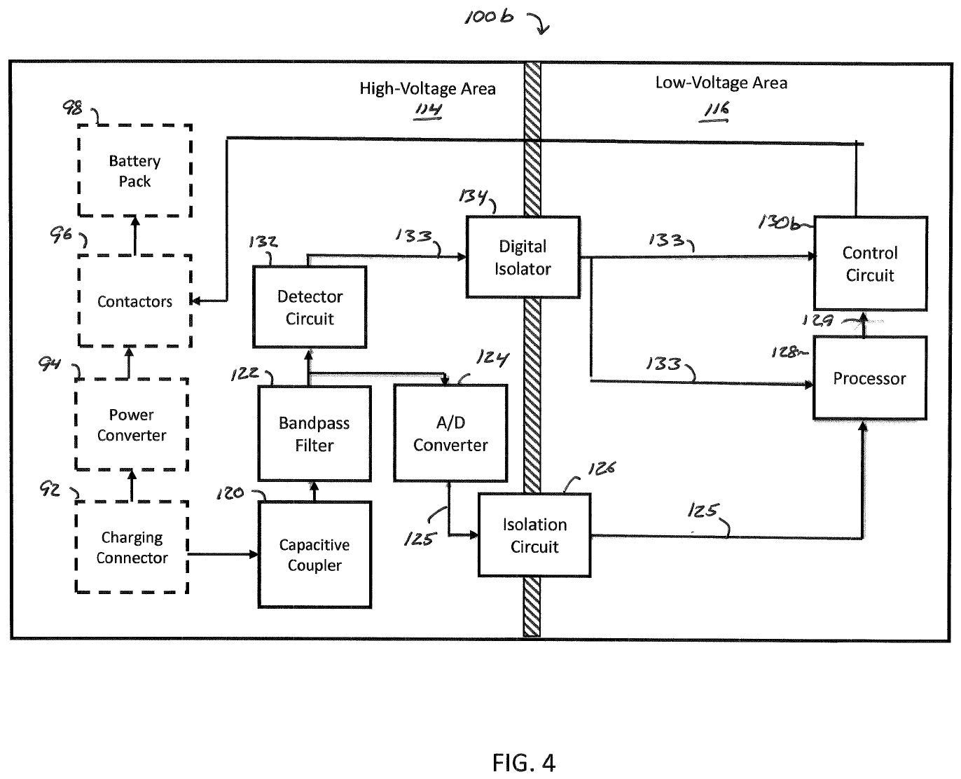

FIG. 4 illustrates a schematic block diagram of an example implementation of a protection circuit 100b in accordance with one or more exemplary embodiments. The protection circuit 100b may be a variation of the protection circuit 100 (FIG. 1) and/or the protection circuit 100a (FIG. 3). The protection circuit 100b may be spread among a high-voltage area 114 of the vehicle 90 and a low-voltage area 116 of the vehicle. The high-voltage area 114 may include the charging socket 92, the power converter 94, the contactor circuit 96, the battery pack 98. The protection circuit 100b generally includes the capacitive coupler circuit 120, the bandpass filter circuit 122, the analog-to-digital (A/D) converter circuit 124, the high-voltage side of the isolation circuit 126, a detector circuit 132, and a high-voltage side of a digital isolator circuit 134. The protection circuit 100b also includes the low-voltage side of the isolation circuit 126, the processor 128, a control circuit 130b, and a low-voltage side of the digital isolator circuit 134 in the low-voltage area 116.

The protection circuit 100b generally includes a hardware-only interlock, with a separate hardware/software path for redundancy. The hardware portion includes the two high-resistive nets with DC-decoupling (capacitive) in the capacitive coupler circuit 120 and the bandpass filter circuit 122. The voltages are read by the A/D converter circuit 124. The results are transferred to the processor 128 via isolation circuit 126 and results may be determined using software prior to closing the contactors. For continuous protection, the A/D converter circuit 124 is continuously queried. Diagnostics may also be performed using software executed by the processor 128 (e.g., compare the digital values 125 to the interlock results. The second path generally provides a redundant operation to prevent closure of the contactors while alternating voltages are detected in the high-voltage area 114.

The control circuit 130b may be a variation of the control circuit 130a (FIG. 3). The control circuit 130b interlocks the closing of the contactors with an enable signal 133. The enable signal 133 is generated by the detector circuit 132 and passed from the high-voltage area 114 to the control circuit 130b in the low-voltage area 116 via the digital isolator circuit 134. While the enable signal 133 is enabled, the control circuit 130b allows the DC contactors to close per the configuration signal 129. While the enable signal 133 is disabled, the control circuit 130b holds (e.g., interlocks) the DC contactors open regardless of the configuration signal 129.

The detector circuit 132 is operational to monitor the high-voltage signal presented by the bandpass filter circuit 122. If the high-voltage signal is detected as a steady-state voltage, the detector circuit 132 may assert the enable signal 133 to remove the interlock on the DC contactors. If the high-voltage signal is detected as an alternating signal, the detector circuit 132 may negate the enable signal 133 to enforce the interlock on the DC contactors.

The digital isolator circuit 134 is operational to pass the enable signal 133 from the high-voltage area 114 to the low-voltage area 116. In various embodiments, the digital isolator circuit 134 may implement opto-coupling, capacitive coupling, and/or inductive coupling. Other isolation circuits may be implemented to meet the design criteria of a particular application.

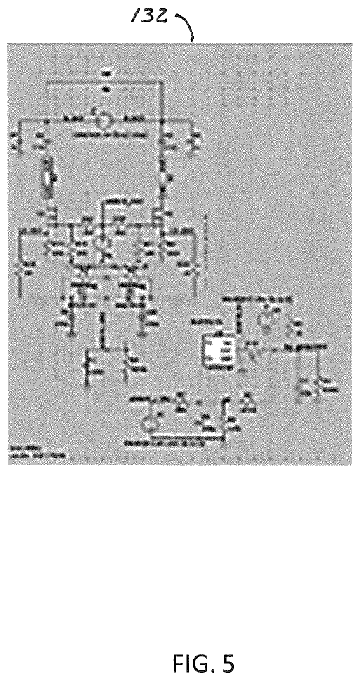

FIG. 5 illustrates a schematic diagram of an example implementation of the detector circuit 132 in accordance with one or more exemplary embodiments.

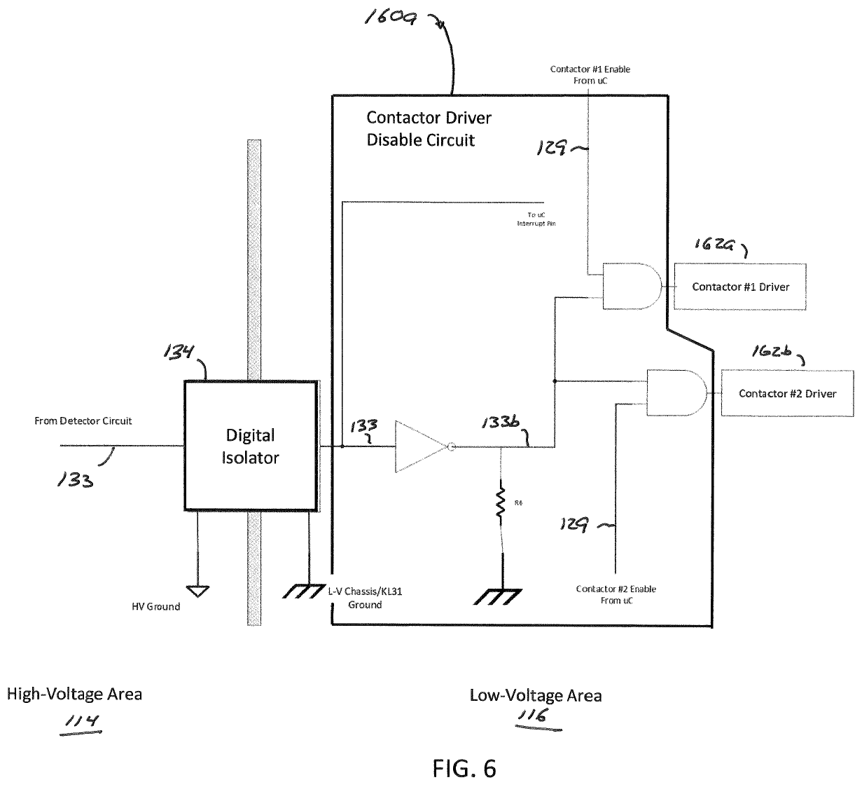

FIG. 6 illustrates a schematic diagram of an example implementation of a contactor driver disable circuit 160a within the control circuit 130b in accordance with one or more exemplary embodiments.

The contactor driver disable circuit 160a may be implemented multiple ways. As illustrated in FIG. 6, a first design of the contactor driver disable circuit 160a uses an inverter gate and logic AND gates to enable/disable the configuration signal 129. While the enable signal 133 is in a logical high state, the inverted enable signal 133b is in a logical low state and the logical AND gates block the configuration signals 129 and generate off commands to the contactor drives 162a-162b. While the enable signal 133 is in a logical low state, the inverted enable signal 133b is in a logical high state and the logical AND gates pass through the on/off commands in the configuration signals 129 to the contactor drives 162a-162b.

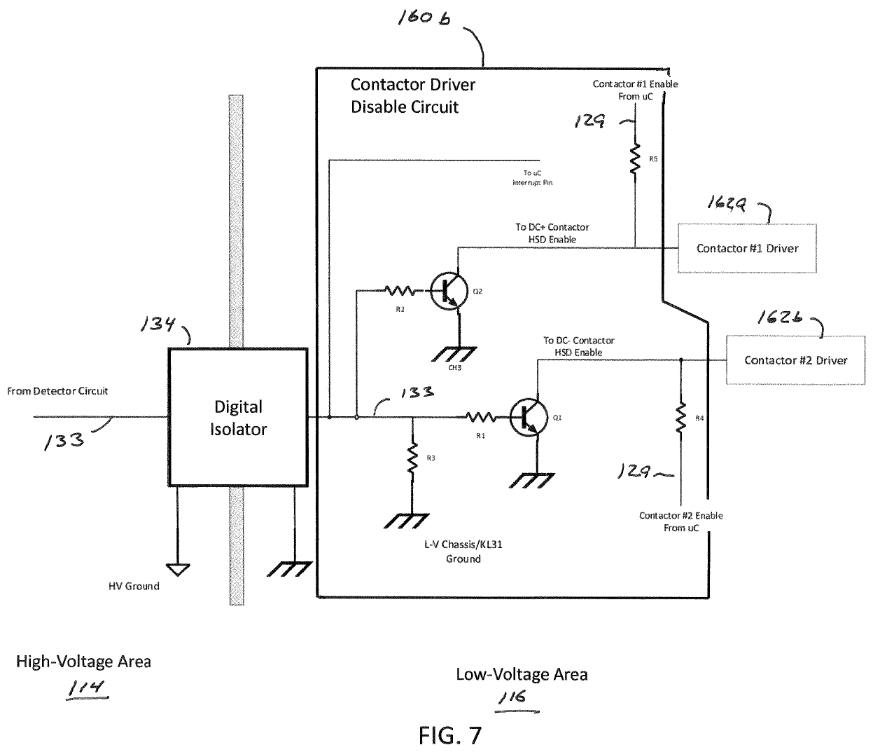

FIG. 7 illustrates a schematic diagram of an example implementation of a contactor driver disable circuit 160b within the control circuit 130b in accordance with one or more exemplary embodiments. The contactor driver disable circuit 160b implements discrete resistors and transistors to provide the same logic as the contactor driver disable circuit 160a.

While the enable signal 133 is in a logical high state, the transistors Q1 and Q2 are in on states and so generate (pull down) off commands to the contactor drives 162a-162b. While the enable signal 133 is a logical low state, the transistors Q1 and Q2 are in off states and so the on/off commands in the configuration signals 129 are presented to the contactor drives 162a-162b.

The protection circuit 100 generally provides a technique of preventing the mixing of DC battery voltage with AC charging voltage in a battery electric vehicle.

The technique involves in the protection circuit use both hardware and software working together to prevent the mixing.

A hardware-only interlock may be included to prevent the mixing.

The detection circuit may use a rectifier circuit to detect AC voltage to determine the enable signal.

The protection circuit may be DC decoupled through capacitors to the high-voltage rails in the high-voltage area of the vehicle.

The technique generally prevents contactors from engaging in the event of a negated enable signal from the detection circuit.

The disabling of the contactors may use logic gates.

The disabling the contactors may use discrete resistors and transistors.

The present disclosure may have various modifications and alternative forms, and some representative embodiments are shown by way of example in the drawings and will be described in detail herein. Novel aspects of this disclosure are not limited to the particular forms illustrated in the above-enumerated drawings. Rather, the disclosure is to cover modifications, equivalents, and combinations falling within the scope of the disclosure as encompassed by the appended claims.

Those having ordinary skill in the art will recognize that terms such as “above,” “below,” “front,” “back,” “upward,” “downward,” “top,” “bottom,” etc., may be used descriptively herein without representing limitations on the scope of the disclosure. Furthermore, the present teachings may be described in terms of functional and/or logical block components and/or various processing steps. Such block components may be comprised of various hardware components, software components executing on hardware, and/or firmware components executing on hardware.

The foregoing detailed description and the drawings are supportive and descriptive of the disclosure, but the scope of the disclosure is defined solely by the claims. As will be appreciated by those of ordinary skill in the art, various alternative designs and embodiments may exist for practicing the disclosure defined in the appended claims.

1. A protection circuit comprising:
an analog-to-digital converter operational to generate a sequence of digital values by digitizing a high-voltage signal within a high-voltage area of a vehicle, wherein the vehicle includes a high-voltage battery and a charging socket;
a control circuit operational to control a plurality of contactors coupled to the charging socket in response to a configuration signal; and
a processor operational to:
determine if the sequence of digital values represents one of an alternating voltage and a steady-state voltage;
assert the configuration signal to command the control circuit to close a pair of DC contactors among the plurality of contactors in response to the sequence of digital values representing the steady-state voltage; and
negate the configuration signal to command the control circuit to open the pair of DC contactors in response to the sequence of digital values representing the alternating voltage to prevent a mixture of the alternating voltage and the steady-state voltage in the high-voltage area.

2. The protection circuit according to claim 1, further comprising:
a detector circuit operational to:
monitor the high-voltage signal;
assert an enable signal while the high-voltage signal is detected as the steady-state voltage; and
negate the enable signal while the high-voltage is detected as the alternating voltage.

3. The protection circuit according to claim 2, wherein:
the control circuit is further operational to:
close the pair of DC contactors in response to the enable signal being asserted and the configuration signal being asserted; and
open the pair of DC contactors in response to at least one of the enable signal being negated and the configuration signal being negated.

4. The protection circuit according to claim 2, further comprising:
a digital isolator circuit operational to transfer the enable signal from the high-voltage area to the control circuit in a low-voltage area of the vehicle.

5. The protection circuit according to claim 2, wherein the detector is implemented solely in hardware.

6. The protection circuit according to claim 1, further comprising:
a bandpass filter circuit connected between the charging socket and the analog-to-digital converter.

7. The protection circuit according to claim 6, further comprising:
a capacitive coupler circuit between the charging socket and the bandpass filter circuit.

8. The protection circuit according to claim 1, further comprising:
an isolation circuit operational to transfer the sequence of digital values from the high-voltage area to the processor in a low-voltage area of the vehicle.

9. The protection circuit according to claim 1, wherein:
the high-voltage signal is approximately 200 to 1000 volts DC.

10. The protection circuit according to claim 1, wherein:
the high-voltage signal is approximately 100 to 260 volts AC.

11. A method for preventing a mixture of an alternating voltage and a steady-state voltage, comprising:
generating with an analog-to-digital converter a sequence of digital values by digitizing a high-voltage signal within a high-voltage area of a vehicle, wherein the vehicle includes a high-voltage battery and a charging socket;
controlling with a control circuit a plurality of contactors coupled to the charging socket in response to a configuration signal; and
determining with a processor if the sequence of digital values represents one of an alternating voltage and a steady-state voltage;
asserting with the processor the configuration signal to command the control circuit to close a pair of DC contactors among the plurality of contactors in response to the sequence of digital values representing the steady-state voltage; and
negating with the processor the configuration signal to command the control circuit to open the pair of DC contactors in response to the sequence of digital values representing the alternating voltage to prevent the mixture of the alternating voltage and the steady-state voltage in the high-voltage area.

12. The method according to claim 11, further comprising:
monitoring with a detector the high-voltage signal with a detector circuit;
asserting an enable signal while the high-voltage signal is detected as the steady-state voltage; and
negating the enable signal while the high-voltage is detected as the alternating voltage.

13. The method according to claim 12, further comprising;
closing the pair of DC contactors in response to the enable signal being asserted and the configuration signal being asserted; and
opening the pair of DC contactors in response to at least one of the enable signal being negated and the configuration signal being negated.

14. The method according to claim 12, further comprising:
transferring with a digital isolator the enable signal from the high-voltage area to the control circuit in a low-voltage area of the vehicle.

15. The method according to claim 12, wherein the monitoring is performed solely in hardware.

16. The method according to claim 11, further comprising:
bandpass filtering a signal between the charging socket and the analog-to-digital converter.

17. The method according to claim 16, further comprising:
capacitively coupling the charging socket to the bandpass filtering.

18. The method according to claim 11, further comprising:
transferring with an isolation circuit the sequence of digital values from the high-voltage area to the processor in a low-voltage area of the vehicle.

19. The method according to claim 11, wherein:
the high-voltage signal is approximately 200 to 1000 volts DC; and
the high-voltage signal is approximately 100 to 260 volts AC.

20. A vehicle comprising:
a high-voltage area that houses a high-voltage battery;
a charging socket accessible from external to the vehicle;
an analog-to-digital converter operational to generate a sequence of digital values by digitizing a high-voltage signal within the high-voltage area;
a control circuit operational to control a plurality of contactors coupled to the charging socket in response to a configuration signal; and
a processor operational to:
determine if the sequence of digital values represents one of an alternating voltage and a steady-state voltage;
assert the configuration signal to command the control circuit to close a pair of DC contactors among the plurality of contactors in response to the sequence of digital values representing the steady-state voltage; and
negate the configuration signal to command the control circuit to open the pair of DC contactors in response to the sequence of digital values representing the alternating voltage to prevent a mixture of the alternating voltage and the steady-state voltage in the high-voltage area.
